(19) United States
(12) Patent Application Publication
(10) Pub. No.: US 2005/0189329 A1
(43) Pub. Date: Sep. 1, 2005

(54) Laser thermal processing with laser diode radiation

(76) Inventors: Somit Talwar, Los Gatos, CA (US); David A. Markle, Saratoga, CA (US)

Correspondence Address: Allston L. Jones;PETERS, VERNY, JONES & SCHMITT, L.L.P., Suite 230, 425 Sherman Avenue, Palo Alto, CA, 94306, US

(21) Appl. No.: 10/838,076

(22) Filed: May 3, 2004

Related U.S. Application Data
(63) Continuation-in-part of application No. 10/653,625, filed on Sep. 2, 2003.

(51) Int. Cl. B23K 26/06; H01L 21/20

(52) U.S. Cl. 219/121.65; 219/121.73; 438/487

(57) ABSTRACT

A method and apparatus for performing laser thermal processing (LTP) using one or more two-dimensional arrays of laser diodes and corresponding one or more LTP optical systems to form corresponding one or more line images. The line images are scanned across a substrate, e.g., by moving the substrate relative to the one or more line images. The apparatus also includes one or more recycling optical systems arranged to re-image reflected annealing radiation back onto the substrate. The use of one or more recycling optical systems greatly improves the heating efficiency and uniformity during LTP.

### CROSS REFERENCE

This application is a continuation-in-part of U.S. patent application Ser. No. 10/653,625, filed on Sep. 2, 2003 and assigned to Ultratech, Inc. This application is also related to U.S. patent application Ser. No. 10/287,864, filed on Nov. 6, 2002, and assigned to Ultratech, Inc.

### BACKGROUND OF THE INVENTION

1. Field of the Invention

The present invention relates to laser thermal processing, and in particular relates to apparatus and methods for performing laser thermal processing with laser diode radiation.

2. Description of the Prior Art

Laser thermal processing (“LTP”) (also referred to as “laser thermal annealing”) is a technique used to anneal and/or activate dopants of source, drain or gate regions of integrated devices or circuits, to form silicide regions in integrated devices or circuits, to lower contact resistances of metal wiring coupled thereto, or to trigger a chemical reaction to either deposit or remove substances from a substrate.

Various devices for performing LTP of a semiconductor substrate are known and used in the integrated circuit (IC) fabrication industry. LTP junction annealing is preferably done in a single cycle that brings the temperature of the material being annealed up to the annealing temperature and back down in a single cycle. If a pulsed laser is used, this requires enough energy per pulse to bring the surface of the entire chip or circuit up to the annealing temperature. Because the required field size can exceed four (4) centimeters-squared (cm²) and the required dose can exceed one (1.0) Joules/cm², a relatively large, expensive laser is required. It is also difficult to achieve good dose uniformity over a relatively large area in a single pulse because the narrow spectral range of most lasers produces a speckled pattern due to interference effects.

Laser diode bars are well-suited to serve as a source of radiation for performing LTP because their wavelengths of 780 nm or 810 nm are readily absorbed in the top layer (i.e., ˜21 microns) of silicon. Diode bars are also efficient converters of electricity to radiation (˜45%) and emit a variety of wavelengths that may be scrambled to provide uniform energy coverage over an extended field size.

U.S. Pat. No. 6,531,681 (the '681 patent) describes how a linear laser diode array, or several linear diode arrays, can be used to form a uniform, narrow line image that can be scanned across a substrate to thermally anneal integrated circuits thereon. The '681 patent also describes how the line image can be placed on a mask and imaged through a projection system to process selected areas of a substrate scanned in synchronism with the mask. However, performing laser thermal processing with a linear array of laser diode bars as described in the '681 patent is problematic. Applications involving silicon substrates have system requirements (i.e., line image width and dwell time) that require relatively high energy densities (e.g. in the range of 1300 W/mm² for a 200 μs dwell time).

U.S. patent application Ser. No. 10/287,864 describes the use of a P-polarized CO₂ laser beam incident at near Brewster's angle to perform LTP of a silicon substrate with integrated circuits formed thereon. As described therein, the use of incident angles at or near Brewster's angle produces very uniform heating of substrates that are otherwise spectrally non-uniform at normal incidence. For example, at normal incidence and at 10.6 microns bare silicon has a reflectivity greater than 30% and silicon oxide has a reflectivity of less than 14%. One benefit of using a CO₂ laser when performing LTP is its ability to deliver a well-collimated beam having relatively high energy density. Another benefit is that the 10.6 μm wavelength emitted by the CO₂ laser is large compared to the various film thicknesses likely to be found on a wafer ready for the annealing step. Small variations in film thickness therefore do not result in large variations in reflectivity as would be the case for a shorter annealing wavelength.

However, the CO₂ laser wavelength of 10.6 μm is best suited for annealing heavily doped silicon substrates, which can absorb sufficient radiation in the top 50 to 100 μm of material. However, for annealing lightly doped substrates or substrates that are doped only in a shallow layer near the top surface, the CO₂ laser radiation passes right through with very little of the incident energy resulting in useful heating.

Laser diodes, on the other hand, emit radiation at wavelengths of 780 nm or 810 nm. These wavelengths are readily absorbed in the top 10 to 20 μm of a silicon wafer independent of the doping level. With laser diodes operating at the short time scales (i.e., 100 μs to 20 ms) associated with LTP, the heating depth is determined by thermal diffusion rather than by the radiation absorption depth (length).

It would therefore be useful to have systems and methods for performing laser thermal annealing at or near the Brewster's angle with polarized laser diode radiation delivered at relatively high energy densities.

### SUMMARY OF THE INVENTION

A first aspect of the invention is a system for performing laser thermal processing (LTP) of a substrate having a Brewster's angle for a select wavelength of radiation. The system includes a two-dimensional array of laser diodes adapted to emit polarized radiation at the select wavelength. The system also includes an LTP optical system having an image plane and arranged to receive the emitted radiation and form an original (first) image at the substrate. The radiation beam is P-polarized and is incident the substrate at an incident angle that is at or near the Brewster's angle. The system further includes at least one recycling optical systems arranged to receive radiation reflected from the substrate and direct the reflected radiation back to the substrate as corresponding at least one recycled radiation beams.

A second aspect of the invention is a method of performing laser thermal processing (LTP) of a substrate. The method includes emitting radiation of the select wavelength from a two-dimensional array of laser diodes. The method also includes receiving the emitted radiation with an LTP optical system and forming therefrom a linearly P-polarized radiation beam that forms an image (e.g., a line image) at the substrate. The method also includes irradiating the substrate with the radiation beam at a first incident angle corresponding to a minimum substrate reflectively for the select wavelength, while scanning the image over at least a portion of the substrate. The method further includes directing radiation reflected from the substrate back to the substrate as a recycled radiation beam during scanning, while preserving the P-polarization of the radiation.

### BRIEF DESCRIPTION OF THE DRAWINGS

FIG. 1 is schematic diagram of the LTP apparatus of the present invention;

FIG. 2A is a schematic diagram of the LTP optical system of the present invention as viewed in the Y-Z plane;

FIG. 2B is a schematic diagram of the LTP optical system of the present invention as viewed in the X-Z plane;

FIG. 3A is a close-up exploded view of the optical elements closest to laser diode array as viewed in the X-Z plane;

FIG. 3B is a close-up exploded view of the optical elements closest to laser diode array as viewed in the Y-Z plane;

FIG. 4A is a close-up view of the elements of the LTP optical system closest to the substrate as viewed in the Y-Z plane;

FIG. 4B is a close-up view of the elements of the LTP optical system closest to the substrate as viewed in the X-Z plane;

FIG. 5 is a plot that shows the variation of reflectivity R (%) with incidence angle e(degrees) of bare silicon along with field oxide films of 300 nm, 400 nm and 500 nm in thickness on a silicon substrate for a wavelength of 800 nm;

FIG. 6 is a plot similar to FIG. 5, showing reflectivities of a 130 nm thick layer of polysilicon overlaying oxide layers having respective thicknesses of 300 nm, 400 nm and 500 nm on a silicon substrate at a wavelength of 800 nm;

FIG. 7A is a close-up schematic diagram of an example embodiment of an LTP system similar to that of FIG. 1, but that further includes a recycling optical system arranged to receive reflected radiation and direct it back toward the substrate as “recycled radiation”;

FIG. 7B is the same as FIG. 7A further including a polarizer, a half-wave plate and an isolation element arranged along axis A1 as part of the LTP optical system, to prevent radiation from returning to the laser diode array;

FIG. 8A is a cross-sectional diagram of an example embodiment of the recycling optical system of FIG. 7 that includes a corner reflector and a collecting/focusing lens;

FIG. 8B is a cross-sectional diagram of an example embodiment of the recycling optical system similar to that of FIG. 8A, that utilizes a two-lens relay and a plane mirror;

FIG. 8C is a top cross-sectional view of an example embodiment of the recycling optical system similar to that of FIG. 8B, that utilizes a two-lens anamorphic relay and a roof mirror having a roof line parallel to the line image on the substrate;

FIG. 8D is a cross-sectional side-view of the recycling optical system of FIG. 8C;

FIG. 9A is a cross-sectional diagram of a variation of the example embodiment of the recycling optical system of FIGS. 8A-8D, wherein the recycling optical system axis A2 is set at an angle outside of the reflected radiation cone angle to achieve an offset in the angle of incidence between the directly incident and recycled radiation beams to prevent radiation from returning to the laser diode array;

FIG. 9B is a schematic diagram based on FIG. 9A showing the relationship between the various axes and cone angles of the different radiation beams and optical systems;

FIG. 9C is a top-down schematic diagram illustrating the embodiment wherein recycling optical system axis A2 is azimuthally rotated relative to the laser diode array and LTP optical system axis A1 by an azimuthal angle φ;

FIG. 10 is a cross-sectional diagram of another example embodiment of the recycling optical system of FIG. 7 that includes a collecting/focusing lens and a grating;

FIG. 11 is a cross-sectional schematic diagram of an example embodiment of an LTP system that employs two laser diode arrays and two corresponding LTP optical systems arranged to irradiate the substrate at similar incidence angles from opposite sides of the substrate normal; and

FIG. 12 is a plan view of an embodiment of the present invention that utilizes two laser diode array radiation sources and six recycling optical systems to recycle the radiation reflected from the substrate surface.

The various elements depicted in the drawings are merely representational and are not necessarily drawn to scale. Certain proportions thereof may be exaggerated, while others may be minimized. The drawings are intended to illustrate various implementations of the invention, which can be understood and appropriately carried out by those of ordinary skill in the art.

### DETAILED DESCRIPTION OF THE INVENTION

The apparatus of the present invention is first described, followed by its methods of operation. The power density requirements and system throughput capabilities are then set forth.

Apparatus

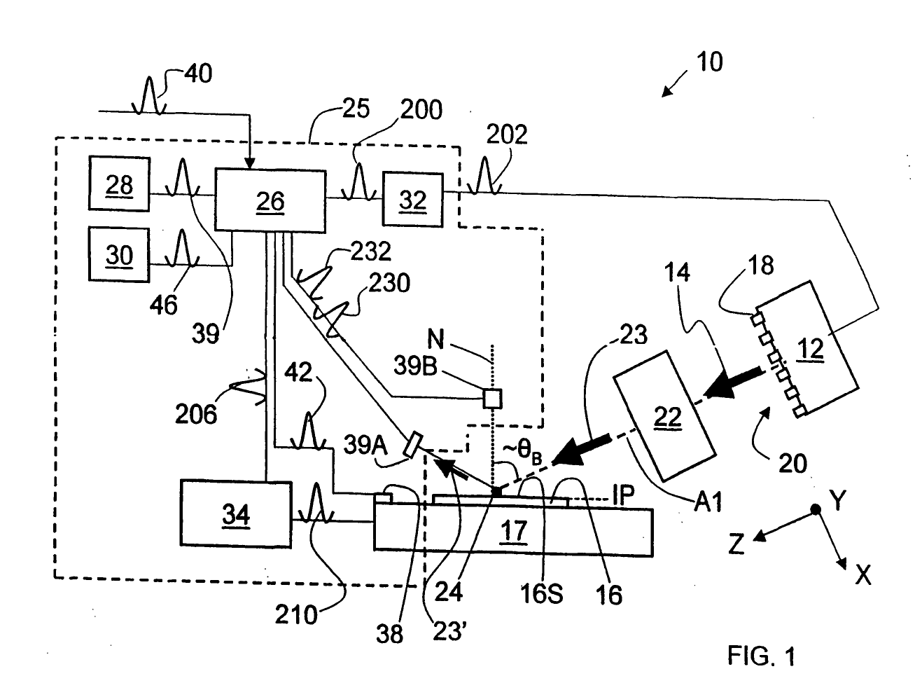

FIG. 1 is a schematic diagram of an example embodiment of the LTP apparatus 10 in accordance with the present invention. The apparatus 10 includes a two-dimensional laser diode array 12 that generates relatively intense radiation 14 used for treating (i.e., irradiating) a substrate 16 supported by a movable stage 17. The substrate surface 16S resides at or near an image plane IP of an LTP optical system 22. These elements as well as others making up apparatus 10 are discussed separately below.

Laser Diode Array

Laser diode array 12 includes a plurality of laser diodes 18 positioned at regularly spaced intervals along a two-dimensional emission face 20 of the array. In an example embodiment, laser diode array 12 is formed by combining (e.g., “stacking”) linear diode arrays that make up rows or columns of the array.

A typical commercially available laser diode array bar (i.e., linear diode array) is a stack of one (1) centimeter linear arrays each containing 60 emitters and spaced about 160 μm apart along the length of the array. Each emitter is about 1 μm wide and about 150 μm long. The orientation of the emitter is such that the largest dimension of the emitter is aligned with the length of the array. The laser diodes 18 typically emit radiation 14 that diverges 10° in a plane defined herein as the Y-Z plane and containing the axis of the individual linear arrays. Further, radiation beam 14 diverges by an amount (e.g., 30°) in a plane orthogonal to the axis of the individual linear diode arrays (defined herein as the XZ plane).

Suitable laser diode array bars are commercially-available from numerous suppliers, including SDL, 80 Rose Orchard Way, San lose, Calif. 95134-1365 (e.g., the SDL 3400 series includes linear arrays 1 cm long and capable of 40 Watts (W) output power), Star Technologies, Inc. of Pleasanton, Calif., Spire, Inc. of One Patriots Park, Bedford, Mass. 01730-2396, Siemens Microelectronics, Inc., Optoelectronics Division, of Cupertino, Calif. (Model SPL BG81), Spectra Diode Labs, Thompson CFS of 7 Rue du Bois Chaland, CE2901 Lisses, 91029 Evry Cedex, France, and IMC, 20 Point West Boulevard, St. Charles, Mo. 63301.

Because the heat generated in the operation of the laser diodes 18 can be substantial and limits the maximum available output power, the laser diode array bars are typically water-cooled to prevent overheating during use.

In a specific example embodiment, laser diode array 12 is made up of 25 rows of laser diodes 18, with each row separated by 1.9 mm and containing 49 laser diodes 18 each measuring 100 μm along the Y-axis and 1 μm along the X-axis (i.e., along the cross-row direction). Each laser diode row is 10mm long and the laser diode array 12 is 24×1.9 mm=45.6 mm wide. The radiation emitted from each laser diode in the Y-Z plane diverges 10° full-width half-max (FWHM) and by 35° FWHM in the X-Z plane. A suitable two-dimensional laser diode array 12 is available from Coherent, Inc, in the line of LightStone™ products (e.g., the diode array sold under the tradename LIGHTSTACK).

In example embodiments, laser diode array 12 generates radiation 14 at a wavelength in the range from about 350 nanometers (nm) to 950 nm, and in a particular example embodiment at 780 nm or at 810 nm. Such wavelengths are particularly effective for processing a silicon substrate having integrated devices or circuit features on the order of one micron or less with source/drain regions of a few tens of nanometers (nm) in thickness.

It is noted here that the present invention is not limited to a laser diode array 12 generating radiation only within the above-stated wavelength range. Commercially available laser diodes emit radiation at wavelengths extending from 380 nm (e.g., GaN blue diodes) through 931 nm. The wavelengths and types of laser diode arrays commercially-available on the market have rapidly expanded, and this trend will likely continue so that numerous additional arrays both in and out of the above-stated wavelength range are expected to become available from manufacturers in the future. Arrays of such future laser diodes may be useful for implementation in the subject invention, particularly those that emit wavelengths absorbed by silicon. Some commercially-available laser diode array bars are capable of generating radiation 14 at a relatively intense power level of 50 W to 100 W in a 1 cm long bar containing a single row of diodes.

In an example embodiment, laser diode array 12 generates radiation having a power density of 150 W/mm² or greater as measured at the substrate.

LTP Optical System

With continuing reference to FIG. 1, apparatus 10 also includes LTP optical system 22 arranged to receive radiation 14 from laser diode array 12 and create a radiation beam 23 that forms a substantially uniform-intensity line image 24 at image plane IP. In the present invention, “line image” means a two-dimensional image having a high aspect ratio (e.g., about 7:1) so that the image is long in one dimension and relatively narrow (“thin”) in the other. Optical system 22 has an optical axis A1 (dashed line).

Radiation beam 23 is P polarized and is incident on substrate 16 at an angle at or near the Brewster's angle θ_{B} (in the FIG. 1 “˜θ_{B}” denotes “at or near Brewster's angle”). The incident angle is defined as the angle between the surface normal N (i.e., the normal vector to substrate surface 16S, as indicated by a dotted line) and the axial ray of radiation beam 23 (the axial ray, not shown, is collinear with optical axis A1). Brewster's angle is defined by the material making up the substrate and the wavelength of the incident radiation. In the present invention, substrate 16 is preferably silicon, such as the type used in IC manufacturing. The Brewster's angle for room temperature silicon is ˜75° at a wavelength of 800 nm and is ˜74° at a wavelength of 10.6 μm. Although Brewster's angle is not defined for a film stack, the presence of films on silicon changes the angle of minimum reflectivity slightly. Nevertheless, in most applications involving films formed on a silicon substrate, the Brewster's angle for the bare silicon wafer is a good approximation.

In an example embodiment of the present invention, the incident angle of radiation beam 23 is within ±10° of the Brewster's angle for the material of the substrate being processed (e.g., silicon). In another example embodiment, the incident angle is between 60° and 80°.

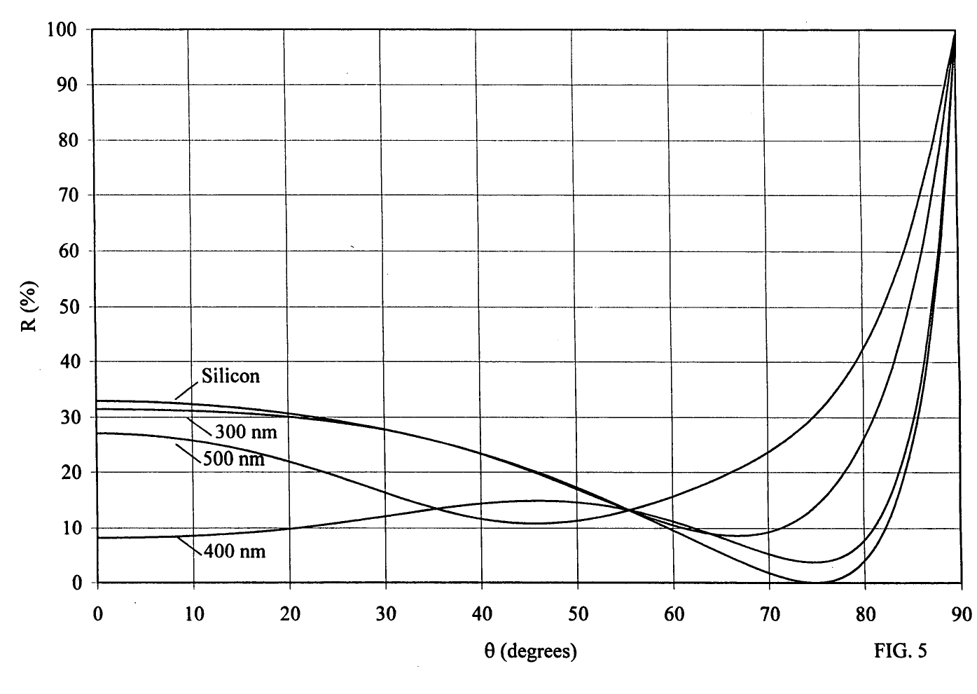

The use of incidence angles near Brewster's angle produces uniform heating on substrates that are spectrally non-uniform at normal incidence because of the uneven distribution of circuit elements containing different films having different spectral characteristics. For example, a given wafer can have one region that is predominately bare crystalline silicon, and another region that is predominately covered with isolation trenches filled with SiO₂ to a depth of 0.5 μm. A third region may have areas containing a 0.1 μm film of poly-silicon on top of an oxide trench in silicon. The reflectivity of each of these regions varies with the angle of incidence as measured relative to surface normal N ( see FIG. 5). By operating at or near Brewster's angle (e.g., generally between 60° and 80°) it is possible to nearly equalize the absorption in the different regions of the substrate and over a wide variety of films and film thicknesses.

Another advantage of operating in this angular range is that the reflectivities of all the films are very low in this region and therefore incident radiation beam 23 is coupled into substrate 16 very efficiently. At normal incidence, about 33% of the incident, 800 nm radiation beam is reflected from bare silicon, and about 3.4% is reflected from the surface of an infinitely thick SiO₂ layer. At an incidence angle of 68°, only about 3% of the radiation is reflected from the bare silicon and from the top surface of the SiO₂ layer. When interference effects from multiple surfaces are considered the result is more complicated, but the total variation in reflectivity from the various possible films is minimized when the P-polarized incident radiation beam 23 is incident at or near the Brewster's angle for silicon.

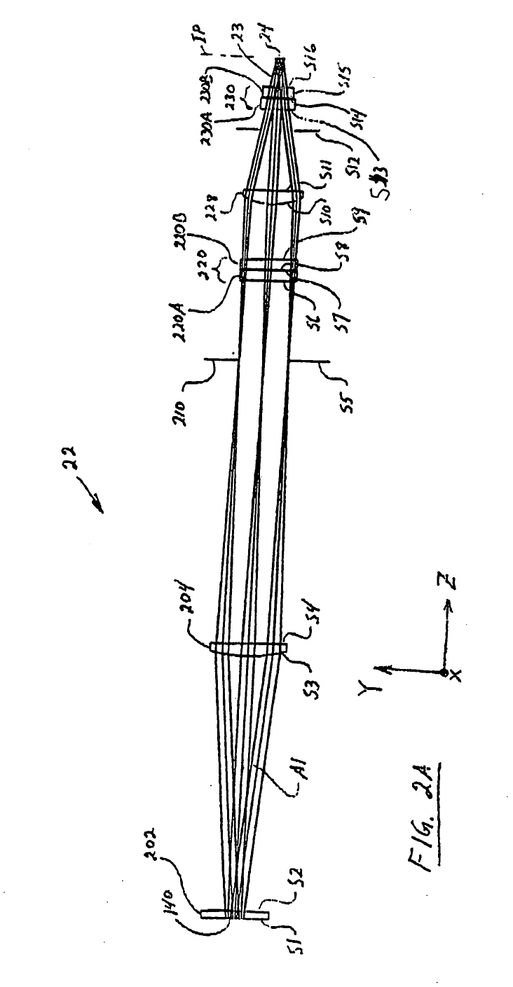

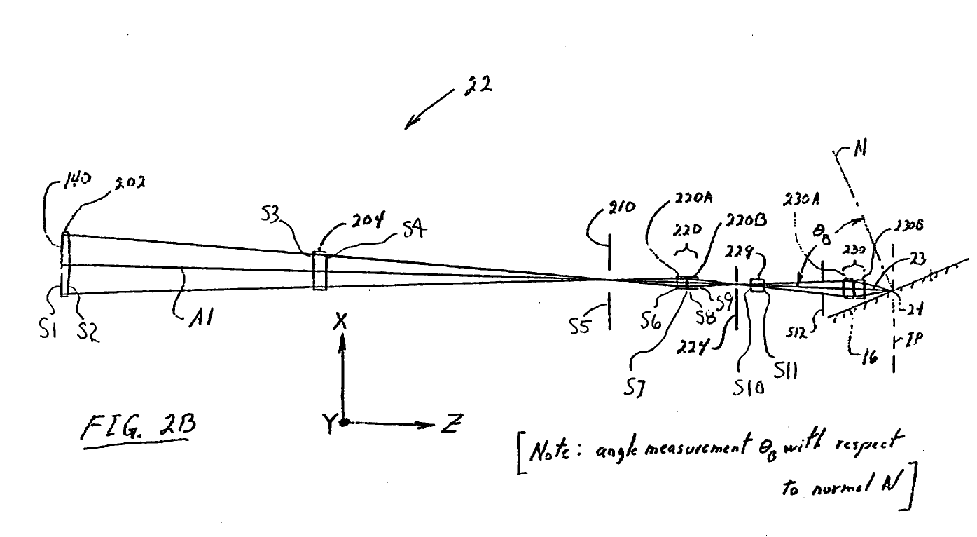

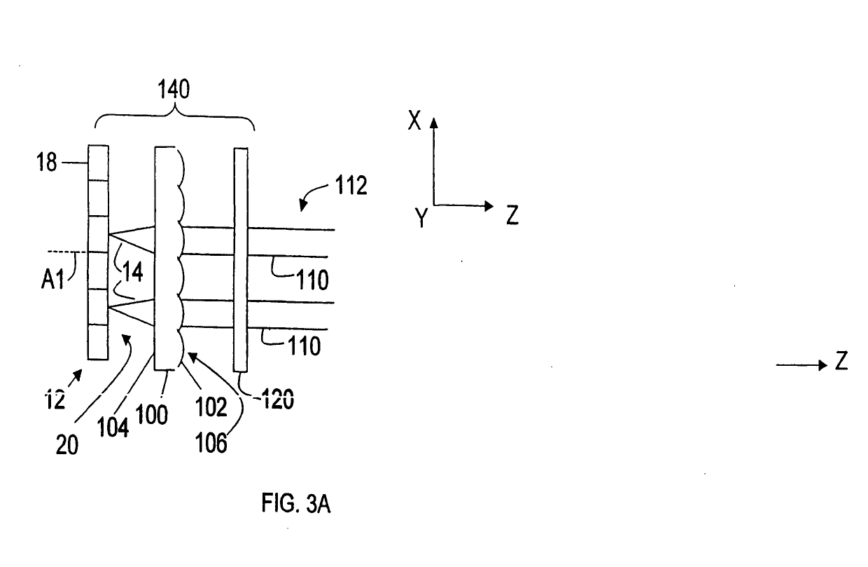

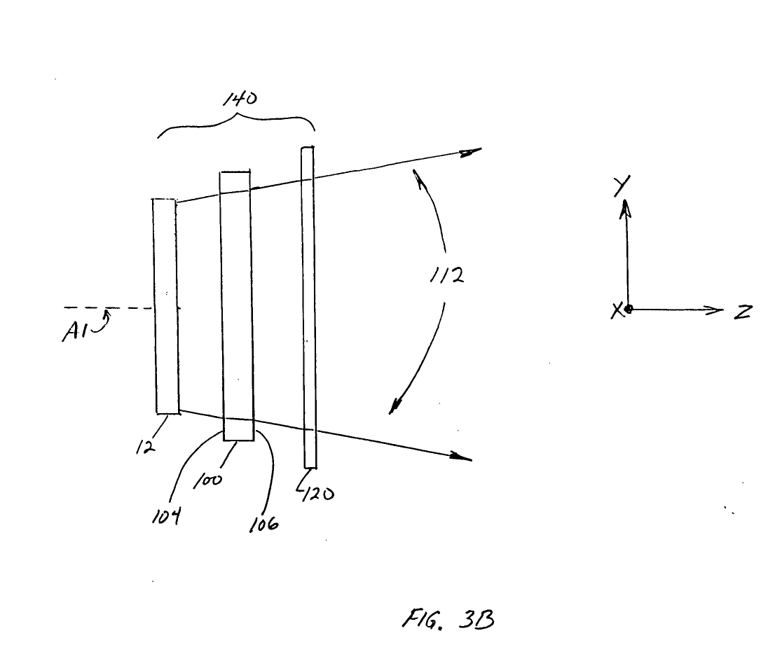

FIGS. 2A and 2B are schematic diagrams of the anamorphic LTP optical system 22 as viewed in the Y-Z and X-Z planes, respectively. As mentioned above, radiation emitted by a laser diode diverges by different amounts in different planes, e.g., by 10° FWHM in the Y-Z plane and by 35° in the X-Z plane. FIGS. 3A and 3B are close-up, exploded, side views of the optical elements closest to laser diode array 12 as viewed in the X-Z and Y-Z planes, respectively.

With reference first to FIGS. 3A and 3B, to collimate the radiation from laser diode array 12 in the X-Z plane, system 22 includes along optical axis A1 a two-dimensional cylindrical lens array 100 arranged immediately adjacent laser diode array 12. Cylindrical lens array 100 is made up of cylindrical lens elements 102 and has an input side 104 and an output side 106. The number of cylindrical lens elements 102 in array 100 corresponds to the number of rows of laser diodes 18 in laser diode array 12. The spacing between adjacent lens elements 102 is preferably the same as that between adjacent rows of laser diodes (e.g., 1.9 mm in the above-described example embodiment) and the lens elements have lens power in the X-Z plane. Thus, N cylindrical lenses produce N collimated and parallel beams 110 in the X-Z plane. Note that these beams still diverge (e.g., by 10°) in the Y-Z plane, which contains the rows of laser diodes.

In an example embodiment, the focal length of each cylindrical lens element is relatively short, e.g., about 3 mm. The N collimated beams 110 (e.g., N=25) are equivalent to a single collimated output beam 112 of a given width (e.g., 47.5 mm). Theoretically the angular spread of the rays in the (substantially) collimated beam 112 could be very small (e.g., 0.024°) and limited only by the 1 μm size of the emitter or by diffraction. In practice, the diode rows wind up slightly bent resulting in a misalignment with the cylindrical lens elements 102. This limits the minimum divergence angle of output beam 112 (e.g., to about 0.3° FWHM).

An example of a suitable cylindrical lens array 100 is available from Limo Micro-Optics & Laser Systems, Bookenburgweg 4, 44319 Dortmund, Germany. The polarization direction of beams 110 is oriented such that the electric field vector is perpendicular to the row direction, i.e., the polarization is in the X-direction. In this case, and with the optical arrangement shown in FIG. 2B, it is not necessary to change the polarization direction. However, other diode arrays can be polarized in the orthogonal direction and these would require changing the polarization direction to correspond to a P-polarization at image plane IP. Thus, with continuing reference to FIGS. 3A and 3B, in an example embodiment, LTP optical system 22 includes an optional half-wave plate 120 arranged immediately adjacent cylindrical lens array 110 to rotate the polarization of the radiation by 90° should a change in polarization direction be required. The half-wave plate 120 can also be used to vary the intensity of P-polarized radiation beam 23 on the substrate by rotating the plate about the optical system axis A1. Since all diode bars emit linearly polarized radiation, the angular orientation of half-wave plate 120 determines the relative amounts of P-polarized and S-polarized radiation incident on the substrate. Since the P-polarized component of radiation beam 23 is strongly absorbed and the S-polarization component mainly reflected, the orientation of the half-wave plate determines the total energy absorbed in the substrate. Thus, the orientation of the half-wave plate can be used to control the total amount of energy absorbed in the substrate.

For the sake of description and ease of illustration, laser diode array 12, cylindrical lens array 100 and optional half-wave plate 120 are grouped together and considered herein to constitute an effective laser radiation source 140 that emits output beam 112 (FIGS. 3A and 3B).

With reference again to FIGS. 2A and 2B, which are orthogonal views of the same LTP relay, LTP optical system 22 further includes, in order along optical axis A1, a cylindrical field lens 202 arranged immediately adjacent effective radiation source 140. Cylindrical field lens 202 has power in the X-Z plane. LTP optical system 22 further includes a cylindrical collimating lens 204 with power in the Y-Z plane, an elliptical pupil 210, a first cylindrical relay group 220 with power in the X-Z plane, and an intermediate image plane 224 as shown in FIG. 2B. System 22 also includes a cylindrical focusing lens 228 with power in the Y-Z plane, and a second cylindrical relay lens group 230 with power in the X-Z plane. In an example embodiment, cylindrical relay lens groups 220 and 230 are air-spaced doublets made up of lenses 220A, 220B and 230A, 230B, respectively.

In this example, cylindrical collimating lens 204 and cylindrical focusing lens 228 form a telecentric, anamorphic relay with a reduction power (ratio) of about 2 which generally can vary between about 1.5 and about 4.5 in the Y-Z plane. Note that a reduction power of 2 corresponds to a magnification magnitude of ½. These cylindrical lenses contribute no power in the X-Z plane (FIG. 2B). Thus the telecentric image produced by the relay shown in FIG. 2A is 5 mm long and subtends a 20° cone angle.

Normally, it would be desirable to have as large a reduction ratio as possible to concentrate the power in line image 24 formed at substrate 16. However the larger the reduction ratio, the larger the cone angle at the substrate and the larger the angular variation in the range of incidence angles in radiation beam 23 as seen by the substrate. For example, if laser diode array 12 was imaged 1:1 onto substrate 16, then the angular spread of the radiation leaving the laser diode array would be duplicated in the radiation beam at the substrate.

To keep the optical design relatively simple, and to limit the variation of incidence angles at substrate 16, it is desirable to limit the angular spread of radiation beam 23 at the substrate to about 20°, which corresponds to the aforementioned demagnification ratio of about 2 in the Y-Z plane. Thus, by way of example, a 10 mm long row of diodes is imaged into a line image 5 mm long.

With reference to FIG. 2B, cylindrical field lens 202 (in cooperation with cylindrical lens array 100 and optional half-wave plate 120) act to form a pupil 210 at a location chosen so that the line final image 24 is telecentric. First cylindrical relay lens group 220 forms an intermediate image of laser diode array 12 at intermediate image plane 224 with a demagnification factor of about 8.3. Second cylindrical relay lens group 230 demagnifies the second intermediate image by another factor of about 8.8 for a total demagnification of about 69 to yield an image size of about 0.66 mm normal to the optical axis A1. Since the image is incident on the substrate at an angle of 66°, the image size on the substrate is increased by 1/cos θ, where θ is the incidence angle. Thus the width of image 24 on the substrate is about 1.62 mm.

In the above example, the magnifications in the X-Z and Y-Z planes were determined by setting an upper limit of 20° to the cone angle in radiation beam 23 as seen by the substrate. However, there is no fundamental limit for the range of incidence angles, although a small range of angles can yield less variation in the energy absorbed across the wafer. If the beam collimation produced by the diode and cylindrical lens arrays had been tighter, then a higher magnification in the X-Z plane could have been used to obtain a narrower line image. Similarly, there is no fundamental reason why the numerical aperture of the laser beam on the substrate has to be identical in both planes. Thus, the reduction power in the Y-Z plane could have been, say between about 1.5× and about 4.5×, and the reduction power in the X-Z plane could have been, say between about 50× and about 150×. The reduction power in the X-Z direction depends on the angular spread in the radiation beams 112 after collimation by cylindrical lens array 100.

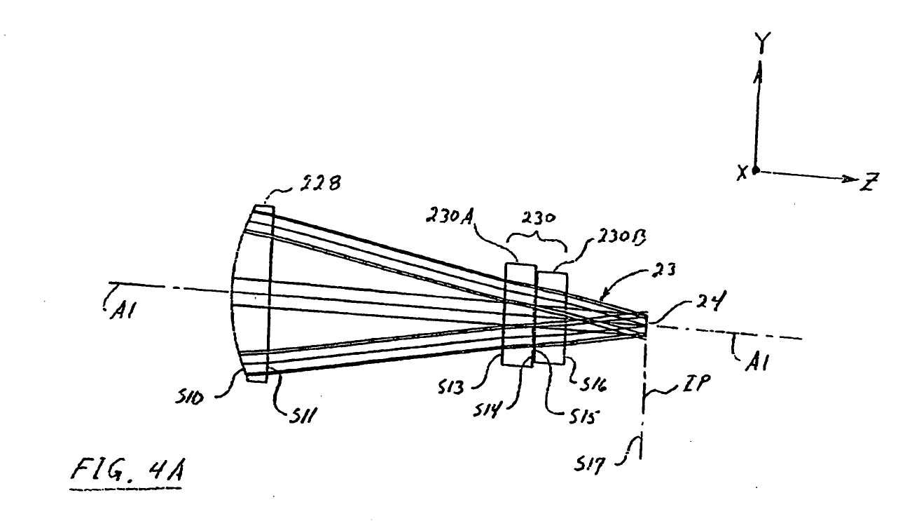

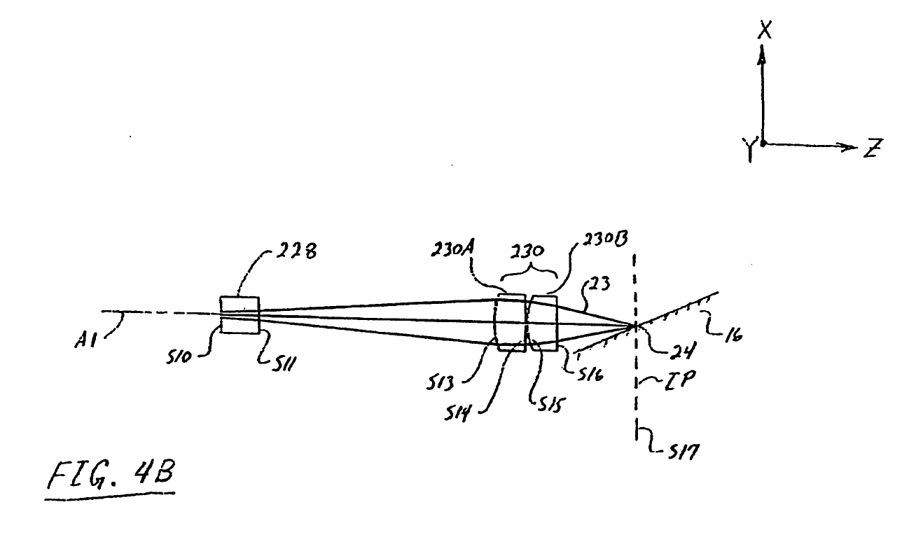

A close-up view of cylindrical focusing lens 228 and cylindrical relay lens group 230 forming line image 24 at substrate 16 as viewed in the Y-Z plane and the X-Z plane is shown in FIGS. 4A and 4B, respectively.

The optical design data for an example embodiment of LTP optical system 22 as described above is set forth in Table 1, below. In the Table, the first column is the surface number, the second column is the surface radius, the third column is the distance to the next surface (thickness or spacing) and the fourth column identifies the lens material. The letter “S” stands for “surface number” S1, S2, etc., and TH stands for “thickness.” All the thickness and radius values are in millimeters (mm). An asterisk (*) indicates an aspheric surface for surfaces S3 and S10, and the aspheric surface data is provided separately below.

TABLE 1
Lens design data for example embodiment of LPT
optical system 22 as illustrated in FIGS. 2A and 2B

| S | Radius (RDY, RDX) | TH | Glass | Element |
|---|---|---|---|---|
| 1 | RDY = 8 RDX = 8 | 6.000 | Silica | Lens 202 |
| 2 | RDY = 8 RDX = −208.824 | 196.238 | | |
| 3* | RDY = 92.224 RDX = 8 | 10.000 | Silica | Lens 204 |
| 4 | RDY = 8 RDX = 8 | 232.209 | | |
| 5 | RDY = 8 RDX = 8 | 47.500 | | Pupil 210 |
| 6 | RDY = 8 RDX = 20.204 | 8.000 | Silica | Lens 220A |
| 7 | RDY = 8 RDX = 8 | 0.500 | | |
| 8 | RDY = 8 RDX = 20.668 | 8.000 | Silica | Lens 220B |
| 9 | RDY = 8 RDX = 8 | 43.100 | | |
| 10* | RDY = 46.026 RDX = 8 | 10.000 | Silica | Lens 228 |
| 11 | RDY = 8 RDX = 8 | 40.943 | | |
| 12 | RDY = 8 RDX = 8 | 21.500 | Pupil | |
| 13 | RDY = 8 RDX = 24.143 | 8.000 | Silica | Lens 230A |
| 14 | RDY = 8 RDX = 8 | 0.500 | | |
| 15 | RDY = 8 RDX = 15.783 | 8.000 | Silica | Lens 230B |
| 16 | RDY = 8 RDX = 8 | 21.510 | | |
| 17 | RDY = 8 RDX = 8 | 0.000 | | Image |

Surface S3
k = −3.410989,
Surface S10
k = −1.011858,

Wherein k is a toroidal aspheric constant defined by the equation:
z=cy²/(1+(1−(1+k)c²y²)^{0.5})
where:
   z is the position of a point on the surface of the torrid normal to its axis and in the direction of the optical axis
   y is the position of a point on the torrid normal to its axis and normal to the optical axis
   c is the surface curvature or the reciprocal of the surface radius
      Image Power Density

In an example embodiment, each row of diodes is capable of generating about 80 W of optical power with water cooling. Assuming an overall efficiency of 70%, the image power density (i.e., the intensity in image 24) is about:
Power=25(80 W)(0.7)/(1.62 mm)(5 mm)=173 W/mm²

This amount of power is significantly less than the 1300 W/mm² (associated with a 200 μs dwell time) needed in the prior art LTP system of the '681 patent.

In an example embodiment, the intensity (power density) in line image 24 is 100 W/mm² or greater.

Control system

With reference again to FIG. 1, in an example embodiment, LTP apparatus 10 further includes a control system 25 (dashed box) that controls the operation of the apparatus. Control system 25 includes a controller 26, an input unit 28 coupled to the controller, and a display unit 30 coupled to the controller. In addition, controller 25 includes a power supply 32 coupled to controller 26 that powers laser diode array 12, a stage controller 34 coupled to stage 17 and to controller 26 that controls the movement of stage 17, and a detector 38 coupled to controller 26 and residing on the stage. Detector 38 is arranged to detect at least a portion of radiation beam 23 delivered to image plane IP when the stage is moved to place the detector in the path of radiation 23 (i.e., to intercept line image 24 at or near image plane IP).

In an example embodiment, control system 25 includes a reflected radiation monitor 39A and a temperature monitor 39B. Reflected radiation monitor 39A is arranged to receive radiation 23 reflected from substrate surface 16S. Reflected radiation is denoted by 23′. Temperature monitor 39B is arranged to measure the temperature of substrate surface 16S, and in an example embodiment is shown arranged along the surface normal N so as to view the substrate at normal incidence at or near where line image 24 is formed. However temperature monitor 39B could also be arranged to view the substrate at the Brewster's angle corresponding to the wavelength band used to measure temperature. Monitors 39A and 39B are coupled to controller 26 to provide for feedback control based on measurements of the amount of reflected radiation 23′ and/or the measured temperature of substrate surface 16S, as described in greater detail below.

In an example embodiment, controller 26 is a microprocessor coupled to a memory, or a microcontroller, programmable logic array (PLA), field-programmable logic array (FPLA), programmed array logic (PAL) or other control device (not shown). The controller 26 can operate in two modes of operation: open-loop, wherein it maintains a constant power on the substrate and a constant scan rate; and closed-loop, wherein it maintains a constant maximum temperature on the substrate surface or a constant power absorbed in the substrate. Since the maximum temperature varies directly as the applied power and inversely as the square root of the scan velocity, in an example embodiment a closed loop control is used to maintain a constant ratio of incident power divided by the square root of the scan velocity. I.e., if P₂₃ is the amount of power in radiation beam 23 and V is the scan velocity, then the ratio P₂₃/V^{1/2} is kept constant.

For closed loop operation, controller 26 receives at least one parameter via a signal (e.g., an electrical signal), such as the maximum substrate temperature (e.g., via signal 232 from temperature monitor 39B), the power P₂₃ in radiation beam 23 (e.g., via signal 42 from detector 38), the reflected power in reflected radiation beam 23′ (e.g., via signal 230 from reflected radiation monitor 39A. Further, controller 26 is adapted to calculate parameters based on the received signals, such as the amount of power absorbed by wafer 16 as determined, for example, from the information in signals 230, 232 and/or 42.

The controller 26 is also coupled to receive an external signal 40 from an operator or from a master controller that is part of a larger substrate assembly or processing tool. This parameter is indicative of the predetermined dose of radiation to be supplied to process the substrate or the maximum temperature to be achieved the substrate. The parameter signal(s) can also be indicative of the intensity, scan velocity, scan speed, and/or number of scans to be used to deliver a predetermined dose of radiation to substrate 16.

Based on the parameter signal(s) received by controller 26, the controller can generate a display signal 46 and send it to display unit 30 to visually display information on the display unit so that a user can determine and verify the parameter signal level(s). The controller 26 is also coupled to receive a start signal that initiates processing performed by the apparatus 10. Such start signal can be signal 39 generated by input unit 28 or external signal 40 from an external unit (not shown), such as a master controller.

Method of Operation

The method of operation of LTP apparatus 10 is now described. With continuing reference to FIG. 1, in response to a start signal (e.g., signal 39 or signal 40) that initiates the system's operational mode, controller 26 is preprogrammed to cause substrate stage 17 (via stage controller 34) to position the substrate in a suitable starting location, to initiate scanning (e.g., moving substrate stage 17), and then to generate a radiation beam 23 of appropriate intensity. A laser diode beam intensity control signal 200 based on the parameter signals as preset by the user or external controller is provided to power supply 32. Power supply 32 then generates a regulated current signal 202 based on the intensity control signal. More specifically, the amount of current in current signal 202 from the power supply is determined by intensity control signal 200. The power supply current is outputted to laser diode array 12 to generate a select level of radiation power 14.

In an example embodiment, controller 26 is preprogrammed to generate a scan control signal 206 based on the parameter signals indicative of the predetermined scan speed and number of scans. The controller 26 generates the scan control signal 206 in coordination with intensity control signal 200 and supplies the scan control signal to stage controller 34. Based on scan control signal 206 and a predetermined scan pattern preprogrammed into the stage controller, the stage controller generates a scan signal 210 to effect movement (e.g., raster, serpentine or boustrophedonic) of stage 36 so that line image 24 is scanned over the substrate 16 or select regions thereof.

In an example embodiment, detector 38 generates a detector signal 42 indicative of the amount of power in radiation beam 23 received at substrate 16, which is a function of the power level of radiation 14 from laser diode array 12 and the transmission of LTP optical system 22. In an example embodiment, controller 26 (or a user directly) determines the intensity control signal 200 and the scan speed. The maximum temperature produced on substrate 16 is approximately proportional to the radiation intensity I₂₃ (i.e., P₂₃/(unit area)) divided by the square root of the scan speed, i.e., I₂₃/V^{1/2}. Hence, in an example embodiment, controller 26 is preprogrammed to achieve a desired maximum temperature by varying either the scan rate, or the laser intensity, or both, to obtain a value of intensity divided by root scan velocity corresponding to the desired maximum temperature. In a further example embodiment, the desired maximum temperature is maintained constant during scanning.

In another example embodiment, an amount of reflected radiation 23′ is measured by reflected radiation monitor 39A, and provides a signal 230 corresponding to the measured power to controller 26. The proportion of radiation beam 23 absorbed by the substrate and the corresponding absorbed power level is then calculated using the incident radiation measurement (e.g., from detector 38) and the reflected radiation measurement. Signal 230 is then used by controller 26 to control the absorbed radiation beam 23 power level provided by laser diode array 12 to substrate 16 to ensure that the correct maximum temperature is maintained in the substrate.

In another example embodiment, substrate temperature monitor 39B measures the temperature of substrate surface 16S and provides a signal 232 to controller 26 that corresponds to the maximum substrate surface temperature. Signal 232 is then used by controller 26 to control the amount of radiation 23 provided by laser diode array 23 to the substrate to ensure that the correct maximum temperature is maintained in the substrate during scanning.

The method also includes scanning line image 24 over at least a portion of the substrate so that each scanned portion sees a pulse of laser diode radiation that takes the surface temperature of the silicon substrate 16 to just under (i.e. to within 400° C. or less) the melting point of silicon (1410° C.) for a period of between 100 μs and 20 ms.

Power Density Requirements for Silicon LTP

The absorbed power density required for annealing silicon substrates (wafers) varies with the “dwell time,” which is the amount of time line image 24 resides over a particular point on substrate surface 16S (FIG. 1). In general, the required power density varies inversely with the square root of the dwell time, as illustrated in Table 2, below:

TABLE 2
Dwell time vs. Power Density

| Dwell Time | Power Density |
|---|---|
| 200 μs | 1200 W/mm² |
| 500 μs | 759 W/mm² |
| 1 ms | 537 W/mm² |
| 2 ms | 379 W/mm² |
| 5 ms | 240 W/mm² |
| 10 ms | 170 W/mm² |

Assuming that a minimum power of 170 W/mm² is required to perform LTP for silicon-based applications, a laser diode array 12 capable of producing such minimum power can perform LTP with dwell times on the order of 10 ms.

System Throughput

It is important to the commercial viability of an LTP system that it be able to process a sufficient number of substrates per unit time, or in the language of the industry, have a sufficient “throughput.” To estimate the throughput for LTP apparatus 10, consider a 300 mm silicon wafer and a line image 5 mm long and 1.62 mm wide. The number of scans over the wafer is given by 300 mm/5 mm=60. Further, for a dwell time of 10 ms, the scan speed is 162 mm/s. The time for one scan is given by (300 mm)/(162 mm/s)=1.85 s. For a stage acceleration rate of 1 g, the acceleration/deceleration time of the stage is (162 mm/s)/(9800 mm/s)=0.017 s. Thus, the time to process one substrate is 60(1.85 s+(2)(0.017 s))=113 s. If the time to input and output a substrate to and from the apparatus is 15 seconds total, then the throughput is given by (3600 s/hr)/(15 s+113 s)=28 substrates/hour, which is a commercially viable throughput value.

Recycling Reflected Radiation

While it is preferable to irradiate substrate 16 with annealing radiation beam (“radiation”) 23 at an incident angle θ that minimizes reflection of this radiation beam, this is not always convenient or possible. This is because the reflectivity of substrate 16 depends on the nature of surface 16S, which can have an uneven distribution of a variety of thin films and other structures residing thereon.

These structures range from bare silicon in the junction areas, to field oxide, to polysilicon on field oxide. It has been estimated a typical integrated circuit comprises 30% to 50% field oxide, about 15% to 20% bare silicon or polysilicon on silicon, and the rest is polysilicon on field oxide. However these proportions vary from circuit to circuit and even across a circuit.

FIG. 5 is a plot of the variation of reflectivity R (%) with incidence angle θ (degrees) for bare silicon along with example field oxide films (300 nm, 400 nm and 500 nm) that are typically present on a silicon substrate ready for junction activation. The plot of FIG. 5 assumes the radiation incident on the substrate has a wavelength of 800 nm and is P-polarized. As can be seen from the plot, for these films the optimum operating point corresponds to an incident angle θ of about 55°, which is the angle where the reflectivities are all equal to about 14%.

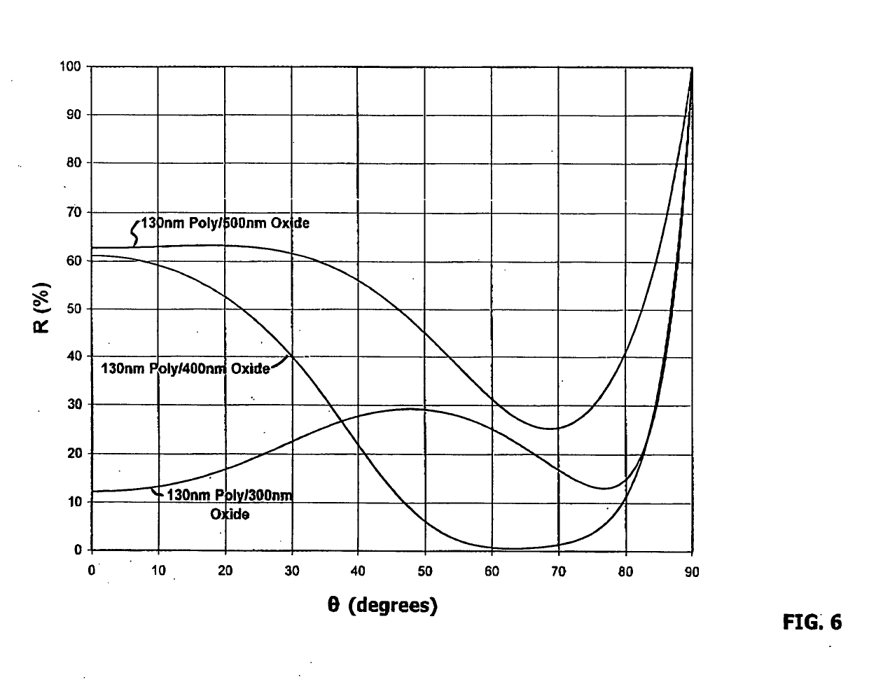

FIG. 6 is a plot similar to FIG. 5, and shows the reflectivities of a 130 nm thick layer of polysilicon on oxide layers having thicknesses of 300 nm, 400 nm and 500 nm, on a silicon substrate. In this case there is no ideal operating incident angle, however 55° is a reasonable choice. In practice, the presence of an activated dopant in the polysilicon and silicon layers renders these regions more metal-like and raises the reflectivity at all angles of incidence.

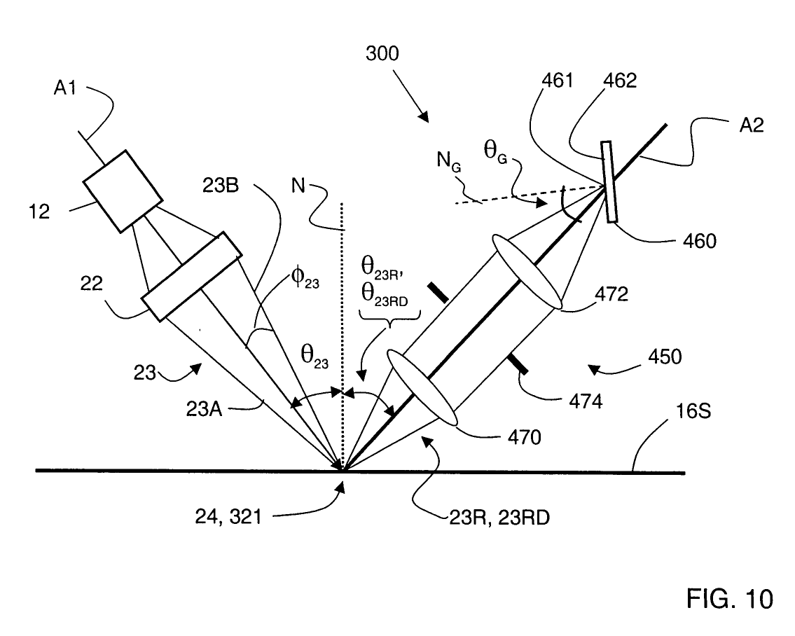

With reference briefly to FIG. 10, discussed in greater detail below, in order to transfer enough energy from radiation source 12 to substrate 16, in an example embodiment radiation beam 23 has a substantial range of incident angles φ at the substrate, i.e., LTP optical system 22 has a substantial numerical aperture NA=sin φ₂₃, wherein φ₂₃ is the half-angle formed by axis A1 and the outer rays 23A or 23B of radiation beam 23. Note that incident angle θ₂₃ is measured between the surface normal N and axis A1, wherein axis A1 also represents an axial ray of radiation beam 23. The angle θ formed by axial ray and the substrate surface normal N is referred to herein as the “central incidence angle” and incidence angles can vary by the range of angles φ₂₃.

In an example embodiment, if a 20° range of incident angles is considered in the plane of incidence, then the plot of FIG. 5 suggests that a spread in incident angles φ₂₃ from about 42° to about 62°, with the central angle at about 520 is a good choice to minimize the variation of reflectivity between the various film stacks.

In practice it is difficult to eliminate the reflection of radiation 23 from substrate surface 16S. Thus, an example embodiment of the present invention involves capturing reflected radiation 23R and redirecting it back toward the substrate as “recycled radiation 23RD, where it can be absorbed by the substrate in order to contribute to the annealing process by further heating the substrate.

There are two main reasons for recycling the reflected energy. One is simply that it improves the efficiency with which energy is coupled into the substrate thus reducing the maximum laser power required and therefore the cost. The second, and even more important reason, is that variations in reflectivity from point-to-point on the wafer lead to variations in the absorbed power and therefore result in an undesirable variation in temperature. Thus, if the resolution of the recycling system can be made high enough, an appreciable improvement in temperature uniformity can be expected.

The required resolution is smaller than the thermal diffusion length (δ) given by:
δ=(D_{T})^{0.5} (1)
where D is the thermal diffusivity (0.9 cm²/sec for silicon) and T is the dwell time of the line image over a point on the substrate.

A typical dwell time of one millisecond would yield a thermal diffusion length of about 300 microns, so that a recycling system with 100 microns resolution would provide a substantial improvement in temperature uniformity.

The required numerical aperture (NA) of the recycling system has to match, as a minimum, the numerical aperture of the directly incident beam. Since the patterns on the wafer have a finite contrast, even under illumination conditions designed to minimize this contrast, it is desirable that the recycling system NA be somewhat larger.

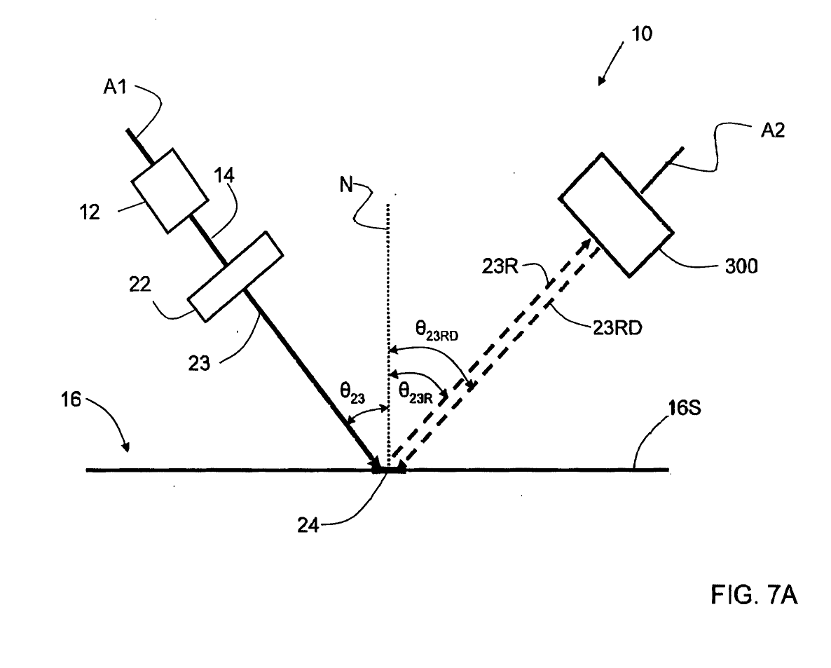

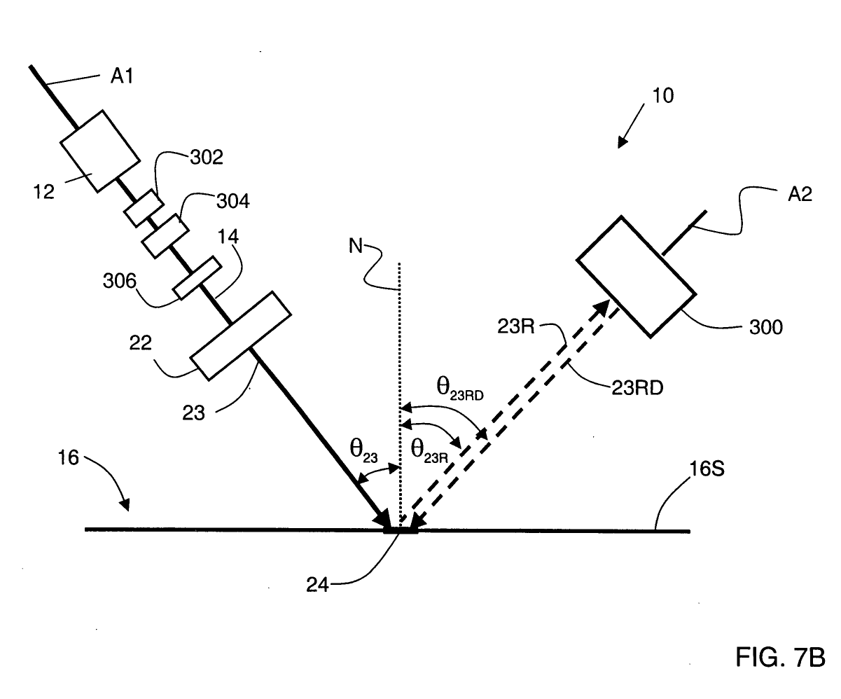

Accordingly, with reference now to FIG. 7A, there is shown a close-up schematic diagram of an example embodiment of the LTA apparatus 10 of the present invention similar to that of FIG. 1, that further includes a recycling optical system 300 arranged to receive reflected radiation 23R and redirect it back to the substrate as recycled radiation 23RD. In FIG. 7A, recycling optical system 300 is arranged along an axis A2 that is coincident with the axis of the reflected radiation so that the recycled radiation is returned to the substrate at the same point and at the same angle of incidence as the original beam. In this case the incidence angle of the reflected beam, θ_{23RD}, is equal and opposite to radiation beam incident angle θ₂₃. In FIG. 7A, the reflected and recycled radiation beams and corresponding angles θ_{23R} and θ_{23RD} are shown separated for ease of illustration.

Ideally, the recycling optical system 300 needs to reimage the line image 24 back on itself at the same scale and with the same orientation as the original (first) line image. There are a number of simple arrangements that will accomplish this. Two such examples are a lens separated from the object by its focal length followed by a corner-cube reflector, and a relay system that images the object on a plane mirror.

FIG. 7B illustrates an example embodiment of the present invention which is the same as FIG. 7A that further includes a polarizer 302, a half-wave plate 304, and an isolation element 306 (e.g., a Faraday rotator or an isolator) arranged along axis A1 (e.g., in emitted radiation beam 14 or incident annealing radiation beam 23) to prevent the recycled radiation from reflecting from the substrate and returning to laser diode array 12. Polarizer 302, half waveplate 304 and isolation element 306 can be considered part of LPT optical system 22.

In operation, the polarizer 302 is aligned to the linear polarization direction of the output beam 14 from the laser diode array 12, and the half wave plate 304 is oriented to produce a polarization 45° from that desired on the substrate. The isolation element 306 provides the additional rotation to produce P-polarized radiation on the substrate. This polarization direction is preserved in the recycled radiation beam, however passage of the recycled radiation through the isolation element a second time produces an additional 45° rotation. Thus, the polarization direction of the recycled radiation in the space between the isolation element and the half wave plate is orthogonal to the polarization direction of the radiation 14 coming directly from the laser diode array 12. After making a second pass through the half wave plate 304, the recycled radiation has a polarization direction normal to that passed by the polarizer 302, resulting in severe attenuation of the recycled radiation beam.

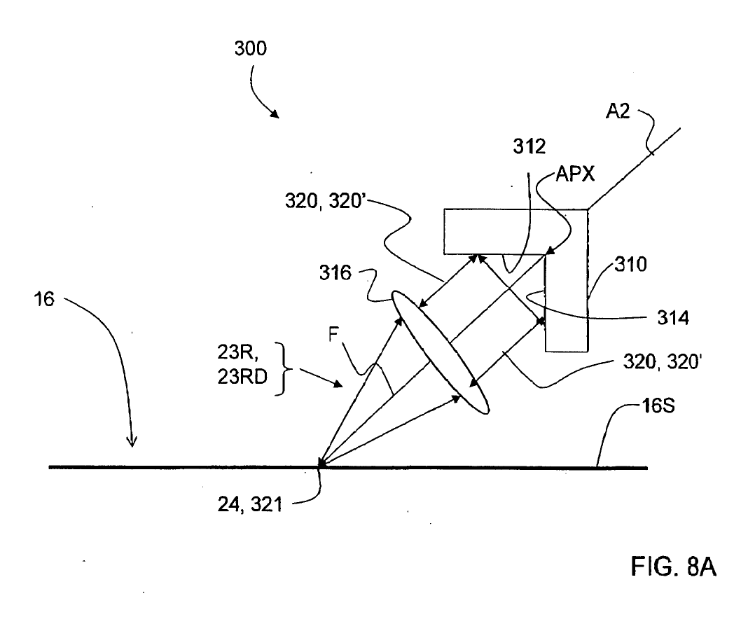

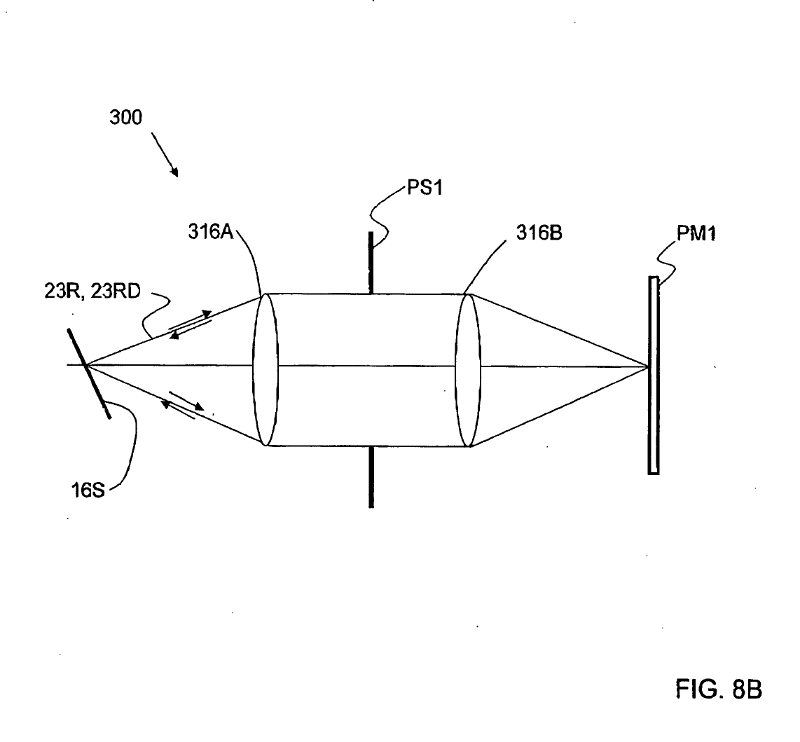

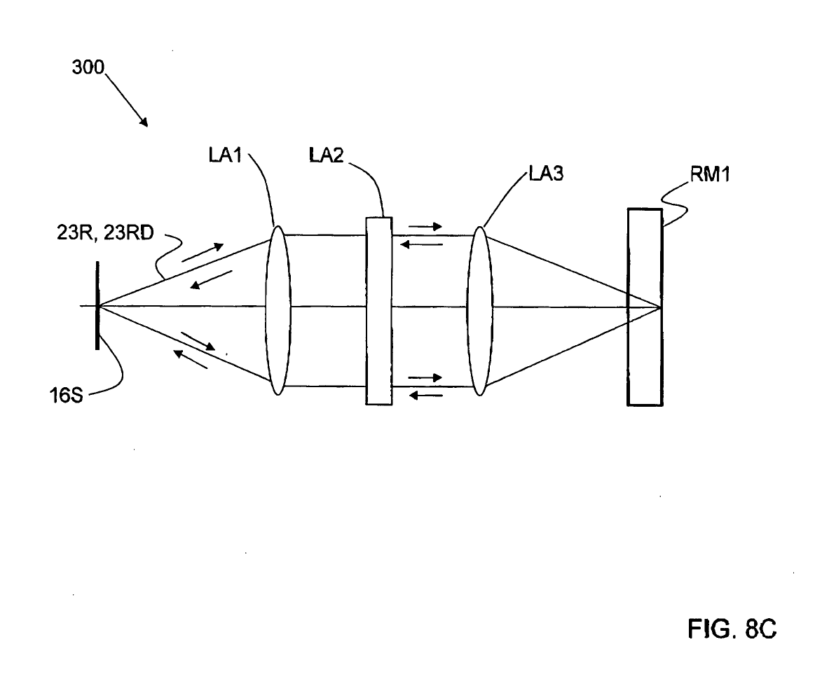

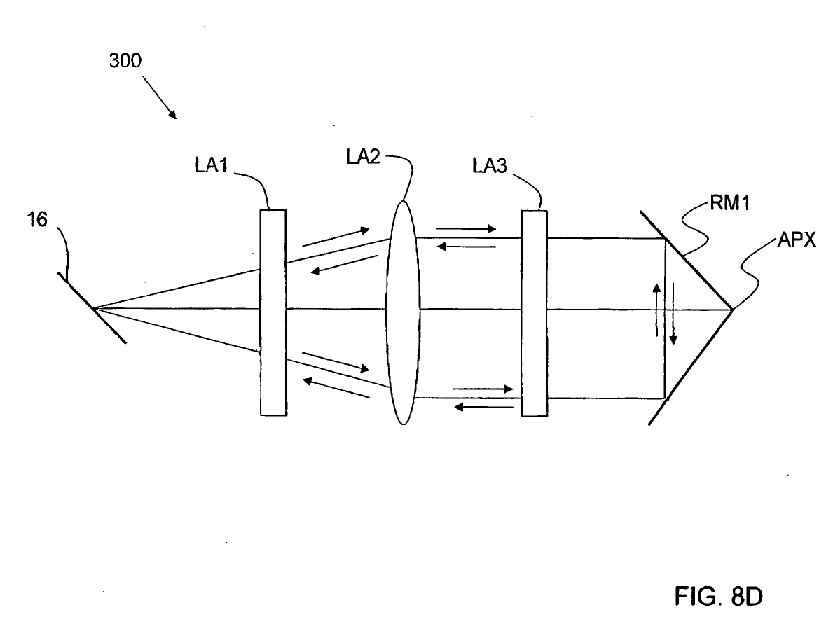

FIGS. 8A, FIG. 8B and FIG. 8C are cross-sectional schematic diagrams of respective example embodiments of recycling optical system 300. The embodiment shown in FIG. 8A includes a hollow corner cube reflector 310 and a collecting/focusing lens 316 having a focal length F that corresponds to the distance from the lens to substrate surface 16S along axis A2. Hollow corner cube reflector 310 has three reflecting surfaces that intersect at right angles, although to simplify the drawing only two of the surfaces, 312 and 314, are shown.

Though it is not essential to the design of systems 300 of FIGS. 8A and 8D in an example embodiment of these systems, the apertures of both the lens 316 and the corner cube 310 are minimized by locating the apex APX of the corner cube on the optical axis A2 of the lens, and one focal length away from the lens. This arrangement creates a recycling system that is a telecentric, 1×, relay with the corner cube located at the pupil. Calculations indicate that the polarization direction of the radiation in the object (i.e., the original or first line image) and image (the “second” line image formed by recycled radiation 23RD) is preserved if metal reflecting surfaces, 312 and 314 and another reflector surface (not shown) are used in a hollow corner cube configuration.

In the operation of optical system 300 of FIG. 8A, lens 316 collects reflected radiation 23R from substrate surface 16S and directs it to corner cube reflector surfaces, 312 and 314 and another reflector surface (not shown), as parallel rays 320. The parallel rays reflect from the three reflector surfaces and are directed back to lens 316 in the exactly the opposite direction, however on the opposite side of axis A2, as parallel rays 320′ that now constitute recycled radiation 23RD. Parallel rays 320′ are collected by lens 316 and are refocused at substrate surface 16S back at their point of origin 321.

FIG. 8B represents an alternate way of constructing recycling optical system 300 of FIG. 8A. In this embodiment, the object (i.e., line image 24) is imaged onto a plane mirror PM1 which returns the image back to the object. The example shown employs collimated radiation between two lenses 316A and 316B separated by the sum of their focal lengths. A pupil stop PS1 located in the collimated path and a focal length away from each lens 316A and 316B renders this system doubly telecentric.

FIGS. 8C and 8D illustrate a hybrid of the example embodiments illustrated in FIGS. 8A and 8B. The top and side views shown in 8C and 8D, respectively, illustrate an anamorphic system with cylindrical lenses LA1, LA2 and LA3 arranged to form an imaging relay in one plane (the top view of FIG. 8C), and a collimating lens and retro mirror in the orthogonal plane (side view of FIG. 8D). In this case, the mirror PM1 of FIG. 8B is replaced with a roof mirror RM1 with its roof-line in the plane of the imaging system.

One difficulty with the configurations illustrated in FIGS. 8A-8D is that if they are employed on the axis of the reflected radiation beam then any recycled radiation that is reflected from the substrate a second time, passes back up the original path to the laser diode array 12. Radiation returned to the laser diode array can cause serious instabilities in the output level and even damage the laser source. If the laser radiation is sufficiently coherent, then interference effects between the directly incident and reflected beams at the substrate can also be problematic. This can be ameliorated, but not eliminated, by separating the angular space occupied by the beams.

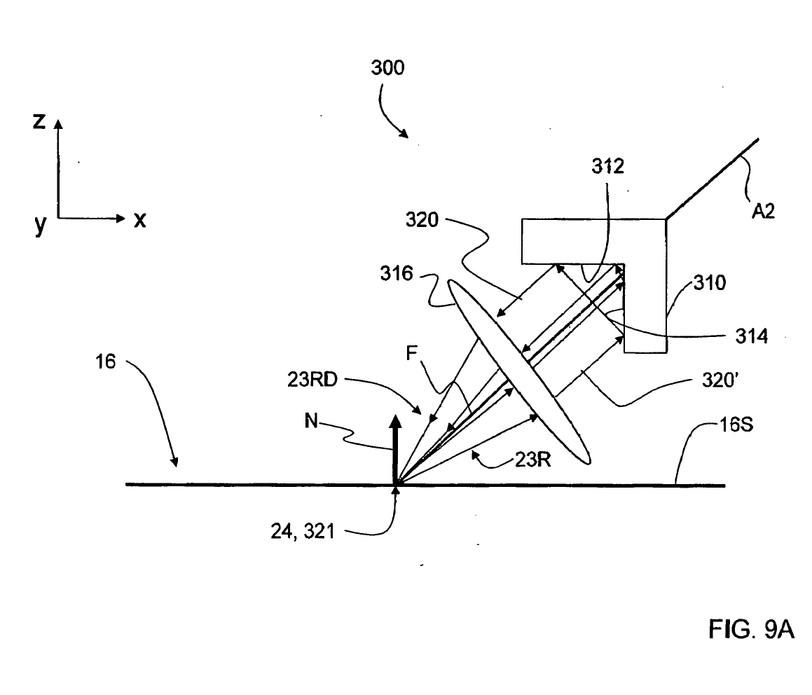

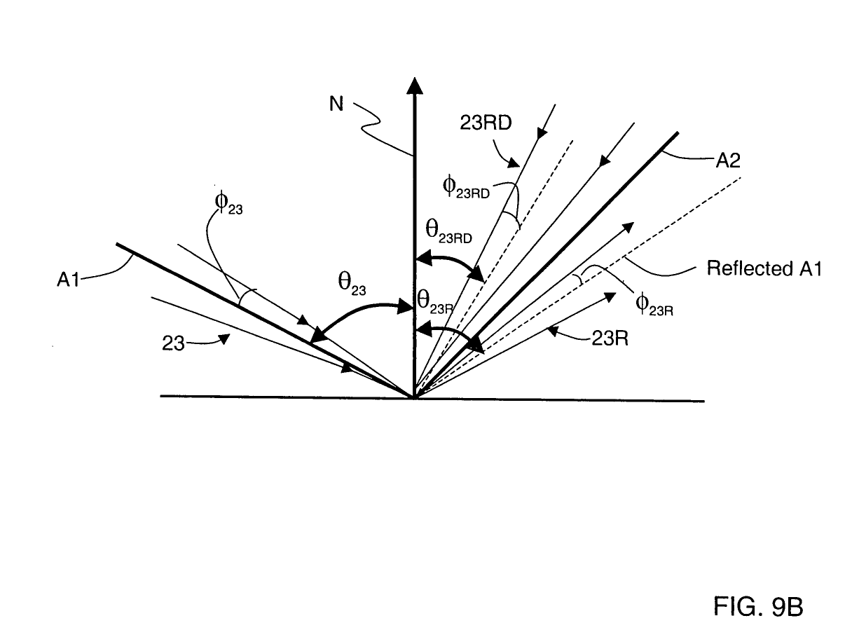

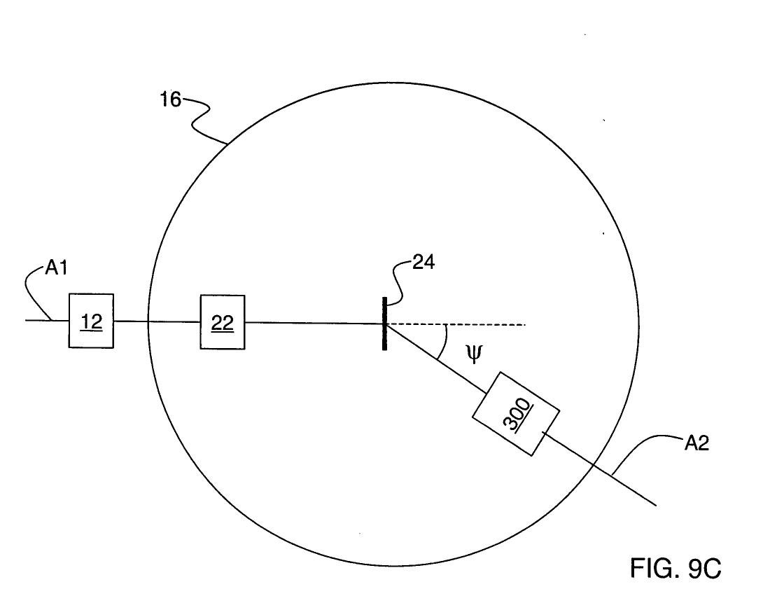

One way of avoiding sending the recycled radiation back to laser diode array 12 is shown in FIGS. 9A and 9B. FIG. 9A is a cross-sectional diagram of a variation of the example embodiment illustrated in FIG. 8A. In system 300 of FIG. 9A, optical axis A2 of the recycling relay passes through the center of the line image displaced in angle so that it lies outside of the reflected radiation cone (the half-angle of which is defined by φ_{23R}), as illustrated schematically in FIG. 9B.

As is shown in FIG. 9A, this arrangement results in an offset in the angles of incidence made by reflected radiation beam 23R and recycled radiation beam 23RD. Note that the position of the incident radiation beam 23 and recycled radiation beam 23RD on substrate 16 remains the same, and that only the incidence angles change. In the embodiment of system 300 of FIGS. 9A and 9B, the relative angular offset between the reflected and recycled radiation beams is exploited to prevent radiation from returning to laser diode array 12.

In the particular example embodiment illustrated in FIG. 9A, a refractive corner cube 310 that employs total internal reflection from each of the three cube faces is not preferred because it does not preserve the polarization direction upon reflection.

In the example embodiment of recycling optical system 300 of FIGS. 9A and 9B, the angle θ_{23RD} associated with recycled radiation beam 23RD is noticeably changed from the initial angles of incidence and reflectance θ₂₃ and θ_{23R}. In general, it is not desirable to have an appreciable difference between angles θ₂₃ and θ_{23RD} because this geometry shifts the incidence angles away from optimum. The incidence angles can be kept close to or at the same value by placing the axis A2 of the recycling system 300 in the middle of the reflected radiation cone, and then azimuthally rotating the A2 axis about an axis normal to the substrate (i.e., the z-axis). The rotation keeps the A2 axis passing through the center of line image 24, as illustrated in FIG. 9C. In this way the relay axis A2 can be moved outside the cone of the reflected radiation 23R and the radiation is returned to the substrate at the same incidence angle (i.e., θ_{23R}=θ_{23RD}), at a different azimuthal angle φ; i.e. at a different angle as measured around the substrate normal N.

In an example embodiment, it is preferred that the reflected radiation be returned by recycling optical system 300 to the same point (e.g., point 321 or the points on line image 24) on the substrate from where it was reflected, to within a fraction of the thermal diffusion length. Otherwise, the reflected radiation can exacerbate the non-uniform heating problems associated with LTP. The embodiment examples of recycling radiation system 300 shown in FIGS. 9A and 9C illustrate how this can be done. In practice, one skilled in the art will understand that the refractive part of the recycling optical system would generally have to incorporate a number of lens elements to achieve a resolution better than or equal to the thermal diffusion distance for the applicable materials and dwell times. Diffraction limits may not necessarily be a problem. For example, if the radiation beams 23 used to heat the substrate have a numerical aperture of 0.2, then the diffraction-limited spot size, assuming a wavelength of 0.8 microns, is about 4 microns. This is well within a typical thermal diffusion length of 100-150 microns.

One shortcoming of the example embodiments shown in FIGS. 8A, 8B, 8C, 8D, 9A and 9C is that they do not directly compensate for the substantial tilt of the object and image planes (i.e., the tilted substrate surface 16S relative to optical axis A2). However, as one skilled in the art will appreciate, the tilted image plane can be accommodated by using tilted lens elements, cylindrical elements, refractive wedges or gratings.

FIG. 10 is a cross-sectional diagram of another example embodiment of a recycling optical system 300 that images an object back on itself while maintaining the scale and orientation of the image, as well as good focus across tilted object and image planes. This system follows the general scheme of the embodiment of FIG. 8B replacing the plane mirror with a tilted grating. The relay lens 450 images the substrate onto a grating 460 having a grating surface 462. In an example embodiment, lens 450 is a high-resolution, telecentric relay having first and second lenses 470 and 472, which image the tilted substrate onto a grating surface tilted in such a way that the image of the tilted object plane lies along its surface. An aperture stop 474 is located between the first and second lenses a distance F1 away from lens 470 and a distance F2 way from lens 472 where F1 and F2 are the focal lengths of the lenses 470 and 472 respectively. Thus, relay 450 is doubly telecentric.

The period of the grating 462 is chosen to diffract the incident beam back on itself and the grating blaze is optimized for this geometry. Thus, the optimum grating period P is given by P=λ/2 sin θ_{G} where λ is the wavelength of the radiation and θ_{G} is the angle of incidence onto the grating relative to the grating surface normal N_{G}. The purpose of the grating is to compensate for the tilted focal plane at the substrate, which would otherwise result in the return image being defocused by an amount depending on its distance from the image point 321. Point 321 coincides with the intersection of the substrate 16 with the optical axes A1 and A2 of LTP optical system 22 and recycling optical system 300, respectively. Note that in the geometry shown in FIG. 10, where relay 450 operates at −1× from the substrate to the grating, that θ_{G}=θ₂₃=θ_{23R}=θ_{23RD}. However, it is not necessary to employ a relay 450 with 1× magnification. In general, disregarding sign conventions, tan θ_{G}=M tan θ₂₃ where M is the magnification of relay 450 from the substrate to the grating.

In the operation of recycling optical system 300 of FIG. 10, reflected radiation 23R is collected by telecentric relay 450, which includes lens 470 and lens 472, which brings the radiation to a focus onto grating surface 462. Grating surface 462 redirects (or more precisely, diffracts) the radiation back to relay 450, which directs what is now recycled radiation 23RD back to substrate surface 16S at or near the point 321 where the reflected radiation originated. Thus, a second image 461 of the original (first) image 24 is formed on the grating surface 462, and a third image 321 is formed superimposed on the original (first) image 24 at the substrate.

A shortcoming with the embodiment of FIG. 10 is that reflected radiation 23R is imaged onto a very small spot or line on the grating on a continuing basis, which can eventually melt or otherwise damage the grating if the reflected energy is appreciable. A similar problem would be encountered using a normal-incidence mirror (not shown) in place of the grating. Therefore, care must be taken in choosing the components for example embodiment of recycling optical system 300 of FIG. 10.

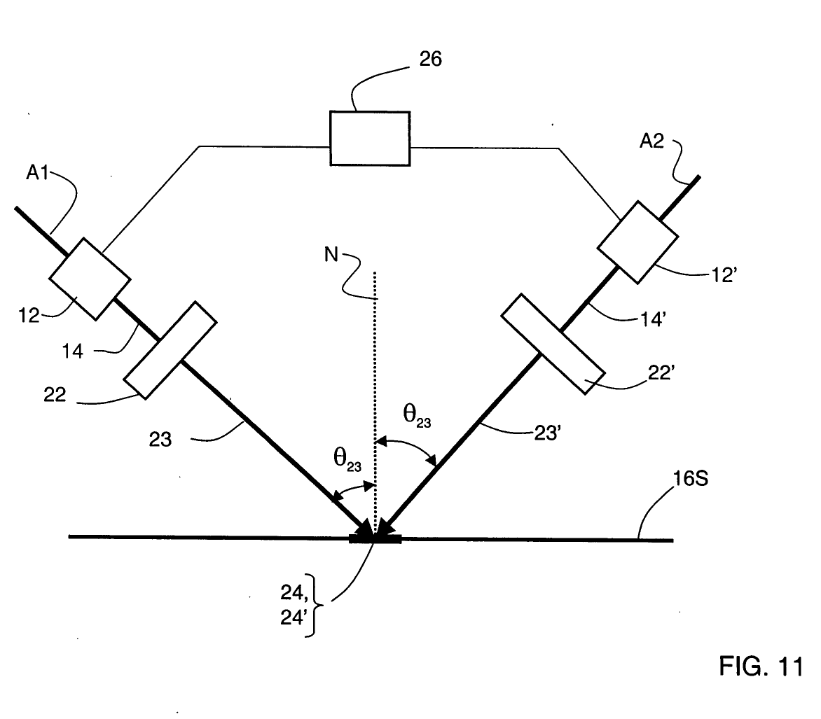

FIG. 11 is a cross-sectional schematic view of an example embodiment of an LTP substrate annealing system, wherein the system employs two LTP optical systems 22 and 22′ having associated two-dimensional laser diode array radiation sources 12 and 12′, respectively. Radiation sources 12 and 12′ are both operatively connected to controller 26. Radiation sources 12 and 12′ emit annealing radiation beams 14 and 14′, respectively. Each annealing radiation beam is received by a corresponding LTP optical system 22 and 22′. The LTP optical systems form respective annealing radiation images 24 and 24′ at substrate surface 16S.

In one example embodiment, LTP optical systems 22 and 22′ are adapted to form images 24 and 24′ that at least butt and may overlap with one another at the substrate. In another example embodiment, images 24 and 24′ are line images. In another example embodiment, at least one of annealing radiation beams 23 and 23′ is incident substrate surface 16S at an incident angle θ₂₃ or θ′₂₃ that is at or near the associated Brewster's angle, which for silicon is ˜75° at 800 nm.

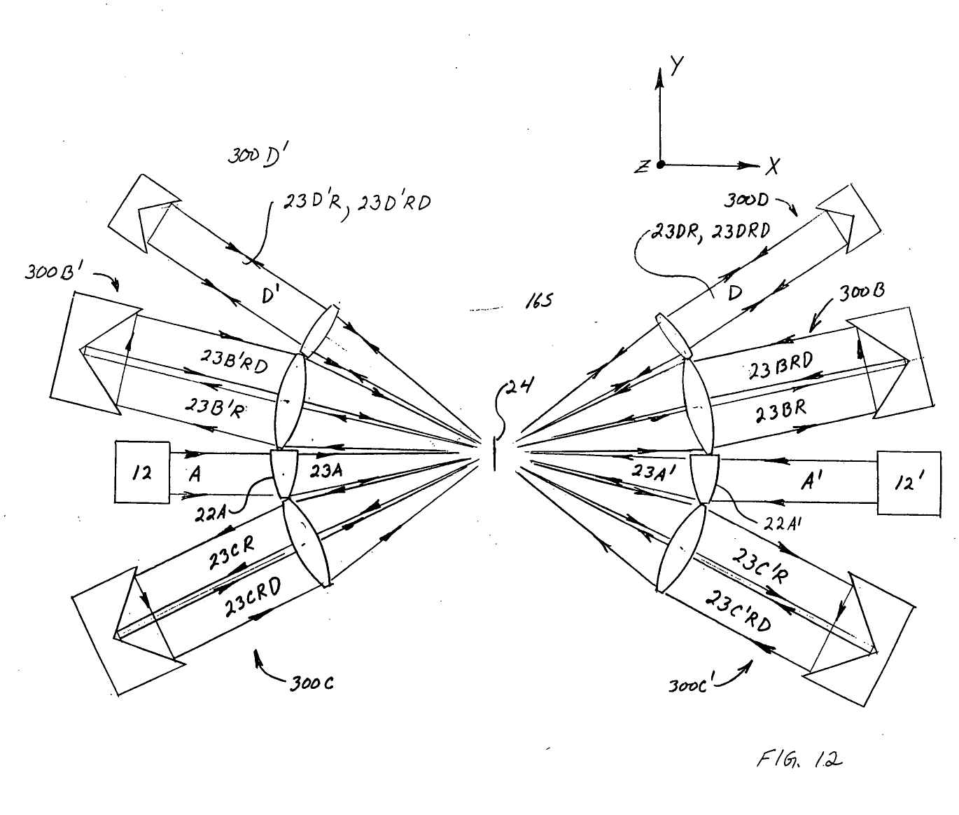

Such an arrangement reduces the demands on the radiation intensity required from the individual laser diode radiation sources 12 and 12′ since their outputs can be effectively combined. The example embodiment of the LTP system of FIG. 12 is not limited to two radiation beams 23 and 23′. In general, any reasonable number of two-dimensional laser diode arrays 12, 12′, 12″, etc., and corresponding optical systems 22, 22′, 22″, etc. can be used to form corresponding images 24, 24′, 24″, etc., (e.g., line images) on substrate surface 16S to achieve the desired intensity and spatial distribution for annealing.

One of the problems inherent in the simple arrangement shown in FIG. 11 is that if the incidence angles of both systems (i.e., θ₂₃ and θ′₂₃) are equal, and they are arranged to be diagonally opposed, then the radiation reflected from one system enters the other. Theoretically, placing a polarizer or a polarizing beam-splitter, and a Faraday rotator or an isolator, and a half-wave plate in the path between the laser diode array 22 and the substrate 16 can solve this problem. Polarized radiation from the laser diode array 22 entering the polarizer from the laser side is transmitted through the polarizer and the polarization direction is rotated by the half-wave plate and again by another 45° by the isolator before it strikes the substrate. However, linearly polarized radiation traveling in the opposite direction from the substrate to the laser is rotated in the same direction as before by the rotator and thereby winds up polarized in a direction normal to the polarizer and therefore is rejected by the polarizer.

Current commercially available isolators have an aperture limit of 10 mm and a power limitation of 500 W/cm². This precludes the use of current generation isolators for a silicon annealing application, however isolators might be used for applications requiring appreciably lower power levels. Also, it is anticipated that future generation isolators will have larger apertures and higher power limitations, making them suitable for the silicon annealing applications.

Not only is it possible to use multiple laser diode arrays 12 and 12′ to achieve a desired intensity, in an example embodiment of the present invention, multiple laser diode arrays (radiation sources) are used in combination with an arbitrary number of recycling optical systems while preserving the desired incidence angles. This example embodiment is illustrated in FIG. 12, which for drawing convenience, shows a view normal to the substrate in which the recycling optical systems 300 have been rotated away from the normal to reflect a 90° incidence angle.

In practice, an incidence angle θ₂₃ between 60° and 80° would likely be used for annealing silicon. In the example embodiment illustrated in FIG. 12, each recycling optical system 300 follows the principle illustrated in FIG. 8A, namely a lens 316 and a hollow, metal-coated corner cube 310 located approximately one focal length away from the lens form a 1X relay that preserves the orientation of the object (i.e., line image 24) on the substrate when it is imaged back on itself.

In most cases, each recycling optical system 300 is employed off-axis so that the input and output beams do not overlap. In the embodiment of FIG. 12 the input radiation beams are 23A and 23A′, which are imaged by respective off-axis LTP optical systems 22A and 22A′. Input radiation beam 23A and 23A′ are arranged so the corresponding reflected beams 23BR, and 23BR′ are not picked up by either LTP optical system 22A or 22A′. Rather, the reflected beams 23BR and 23B′R are picked up by respective recycling optical systems 300B and 300B′ and imaged back onto the substrate. Systems 300B and 300B′ preserve the incidence angles while changing the azimuthal angle φ (FIG. 9C).

Radiation reflected from the substrate a second time is again collected by corresponding recycling optical systems 300C and 300C′ and imaged back on the substrate as recycled radiation beams 23CRD and 23C′RD. Radiation reflected from the substrate a third time is again collected by corresponding recycling optical systems 300D and 300D′ and imaged back on the substrate as recycled radiation beams 23DRD and 23D′RD. This time, the reflected radiation beams from beams 23DRD and 23D′ RD are returned back to recycling optical systems 300C and 300C′ from where they progress to systems 300B and 300B′ and eventually return to laser diode arrays 12 and 12′.

In the present example embodiment, each of the two input beams 23A and 23A′ reflect from substrate surface 16S seven times before returning to the laser diode array 12 or 12′. Even if a single reflection absorbed only half of the incident radiation, after seven reflections less than 1% of the original radiation would be returned to the corresponding laser diode array. This would be further attenuated by the optical efficiency of the extended optical trains of the recycling optical systems.

The example embodiments discussed above in connection with FIGS. 11 and 12 use a select number of laser diode arrays and recycling optical systems for the sake of illustration. However, it follows from the above that the present invention encompasses an arbitrary number of laser diode array sources arranged in such a way that they do not interfere with one another (i.e., the radiation does not end up returning to one of the laser diode arrays in substantial amounts).

Furthermore, in an example embodiment of the present invention, an arbitrary number of recycling radiation systems 300 are arranged similar to the arrangement shown in FIG. 12 to recycle any reflected radiation a number of times back to the line image on the substrate while avoiding having the recycled radiation returning to one of the laser diode arrays in substantial amounts. This example embodiment includes an arrangement wherein highly oblique incident angles are used. Further, it is possible to preserve the incident angles and the polarization direction in the recycled beams in such an arrangement.

In the foregoing Detailed Description, various features are grouped together in various example embodiments for ease of understanding. The many features and advantages of the present invention are apparent from the detailed specification, and, thus, it is intended by the appended claims to cover all such features and advantages of the described apparatus that follow the true spirit and scope of the invention. Furthermore, since numerous modifications and changes will readily occur to those of skill in the art, it is not desired to limit the invention to the exact construction and operation described herein. Accordingly, other embodiments are within the scope of the appended claims.

1. A system for performing laser thermal processing (LTP) of a substrate having a Brewster's angle for a select wavelength of radiation, comprising:
a two-dimensional array of laser diodes adapted to emit polarized radiation at the select wavelength;
an LTP optical system having an image plane and arranged to receive the emitted radiation and form a first image at the substrate, wherein the radiation beam is P-polarized and is incident the substrate at an incident angle that is at or near the Brewster's angle;
at least one recycling optical system arranged to receive radiation reflected from the substrate and direct the reflected radiation back to the substrate as corresponding at least one recycled radiation beams.

2. The system of claim 1, wherein each of the at least one recycling optical systems is arranged such that the corresponding at least one recycled radiation beams are incident the substrate at an incident angle that is at or near the Brewster's angle.

3. The system of claim 1, wherein each of the at least one recycling optical systems is adapted to form the corresponding one or more recycled radiation beams with a polarization identical to the polarization of the incident radiation beam.

4. The system of claim 1, wherein each of the at least one recycling optical systems forms corresponding one or more second images of the first image that at least partially overlap the first image.

5. The system of claim 4, wherein the one or more second images are not inverted relative to the first image.

6. The system of claim 1, wherein the LTP imaging system includes an isolator or Faraday rotator and a polarizer arranged to prevent recycled radiation reflected from the substrate from returning to the radiation source.

7. The system of claim 1, wherein each of the at least one recycling optical systems forms from the corresponding one or more recycled radiation beams a second image that is scanned over the substrate, wherein the scanned images have a resolution equal to or less than a thermal diffusion length corresponding to a dwell time associated with the scanned image.

8. The system of claim 1, wherein each of the at least one recycling optical systems is adapted to return the reflected radiation to the substrate with a resolution less than or equal to a thermal diffusion length corresponding to a dwell time associated with the scanned image.

9. The system of claim 1, wherein the incident radiation beam has a first numerical aperture, and wherein at least one of the at least one recycling optical systems has a second numerical aperture greater than or equal to the first numerical aperture.

10. The system of claim 1, wherein the incident radiation beam has a radiation beam cone angle that occupies a portion of angular space, wherein the at least one recycled radiation beams have corresponding recycled radiation beam cone angles that occupy a different portion of angular space, and wherein the reflected radiation beam cone angle and the recycled radiation beam cone angles do not overlap in angular space.

11. The system of claim 1, wherein the at least one recycling optical systems are arranged relative to the laser diode array such that recycled radiation does not return to the laser diode array after a second reflection from the substrate.

12. The system of claim 1, wherein at least one of the at least one reflected recycled radiation beams and the incident radiation beam have different respective azimuthal angles.

13. The system of claim 1, wherein:
the incident radiation beam has a first azimuthal angle;
the at least one recycled radiation beams have corresponding at least one recycled radiation beam azimuthal angles; and
wherein the incident radiation beam azimuthal angle and the recycled radiation beam azimuthal angles are selected so that recycled radiation reflected from the substrate cannot return to the laser diode array.

14. The system of claim 1, wherein at least one of the at least one recycling optical systems includes a collecting/focusing lens and a corner cube reflector.

15. The system of claim 1 wherein at least one of the at least one recycling optical systems includes an optical relay that images the first image onto a plane mirror

16. The system of claim 1 wherein at least one of the at least one recycling optical systems includes a relay and a diffraction grating, wherein the diffraction grating is oriented to produce an image plane at the substrate that is parallel to the substrate.

17. A laser thermal processing (LTP) system, comprising:
a laser diode array adapted to emit radiation at a select wavelength;
an LTP optical system having an image plane and arranged to receive the radiation and create therefrom an incident radiation beam having an oblique incident angle relative to a substrate and that forms a first image on the substrate arranged in the image plane; and
one or more recycling optical systems each adapted to receive radiation reflected from the substrate and return the reflected radiation to the substrate as a recycled radiation beam.

18. The system of claim 17, wherein each of the one or more recycled radiation beams is incident the substrate at an angle equal to the oblique incident angle.

19. The system of claim 17, wherein each of the one or more recycled radiation beams is incident the substrate at an angle that is at or near Brewster's angle.

20. The system of claim 19, wherein the incident radiation beam is P-polarized, and wherein each of the one or more recycling optical systems is adapted to form corresponding P-polarized recycled radiation beams.

21. The system of claim 17, wherein each of the one or more recycling optical systems is adapted to form one or more corresponding noninverted second images from the original image and superimpose the one or more corresponding noninverted second images onto the original image at the substrate.

22. The system of claim 17, wherein at least one of the one or more recycling optical system is adapted to form a second image on the substrate.

23. The system of claim 17, wherein each of the one or more recycling optical systems forms a second image that is scanned over the substrate, wherein the second image has a resolution equal to or less than a thermal diffusion length corresponding to a dwell time associated with the scanned second image.

24. The system of claim 17, wherein the incident radiation beam has a incident cone angle in angular space and the one or more reflected recycled radiation beams have corresponding recycled radiation beam cone angles in angular space, and wherein the incident radiation beam cone and the one or more recycled radiation beam cone angles do not overlap in angular space.

25. The system of claim 17, wherein at least one of the one or more recycled radiation beams and the incident radiation beam do not have directly opposing azimuthal angles.

26. The system of claim 17, wherein:
the incident radiation beam has a first azimuthal angle;
the one or more recycled radiation beams have corresponding one or more recycled radiation beam azimuthal angles; and
wherein the incident radiation beam azimuthal angle and the recycled radiation beam azimuthal angles are selected so that recycled radiation reflected from the substrate cannot return to the laser diode array.

27. The system of claim 17, wherein least one of the one or more recycling optical systems has an optical axis that is arranged at an angle relative to a surface normal of the substrate, wherein said angle is different from the oblique angle associated with the LTP optical system.

28. The system of claim 17, wherein at least one of the one or more recycling optical systems includes a collecting/focusing lens and a corner cube reflector.

29. The system of claim 17, wherein at least one of the one or more recycling optical systems includes an optical relay that images the first image onto a plane mirror.

30. The system of claim 17, wherein at least one of the one or more recycling optical systems includes a relay that images the first image onto a diffraction grating, wherein the diffraction grating is oriented such that the at least one recycling optical system has an image plane located at the substrate and that is oriented parallel to the substrate plane.

31. The system of claim 17, wherein the LTP optical system has first numerical aperture, the one or more recycling optical systems each have corresponding one or more second numerical apertures, and wherein the one or more second numerical apertures are greater than or equal to the first numerical aperture.

32. The system of claim 17, wherein the first image is a line image.

33. A system for performing laser thermal processing (LTP) of a substrate having a Brewster's angle, comprising:
first and second two-dimensional laser diode arrays each adapted to emit respective first and second beams of P-polarized radiation;
respective first and second LTP optical systems arranged to receive corresponding ones of the first and second beams of P-polarized radiation and create therefrom respective first and second annealing radiation beams that form respective first and second images at the substrate; and
wherein at least one of the first and second annealing radiation beams is incident the substrate at or near the Brewster's angle.

34. A system for performing laser thermal processing (LTP) of a substrate having a Brewster's angle, comprising:
multiple two-dimensional laser diode radiation sources that emit respective annealing radiation beams of a select wavelength; and
corresponding multiple LTP optical systems each arranged to receive corresponding beams of the annealing radiation and form therefrom a corresponding image on the substrate, thereby forming multiple images on the substrate, wherein the multiple images at least partially overlap.

35. The system of claim 34, wherein the multiple images are superimposed on one another.

36. The system of claim 34, wherein the substrate is scanned relative to the multiple images.

37. The system of claim 34, wherein the annealing radiation is P-polarized.

38. A method of performing laser thermal processing (LTP) of a substrate, comprising:
emitting radiation of the select wavelength from a two-dimensional array of laser diodes;
receiving the emitted radiation with an LTP optical system and forming therefrom a linearly P-polarized radiation beam that forms a first image at the substrate;
irradiating the substrate with the radiation beam at a first incident angle corresponding to a minimum substrate reflectively for the select wavelength, while scanning the first image over at least a portion of the substrate; and
directing radiation reflected from the substrate back to the substrate as a recycled radiation beam during said scanning.

39. The method of claim 38, wherein said directing includes causing the recycled radiation beam to have a second incident angle corresponding to the minimum substrate reflectivity at the select wavelength.

40. The method of claim 38, wherein said directing includes forming one or more additional images from the first image and superimposing the additional images on the first image at the substrate.

41. The method of claim 38, including forming the first image as a line image.

42. A method of performing laser thermal processing (LTP) of a substrate having a Brewster's angle, comprising:
focusing annealing radiation onto a portion of the substrate;
receiving annealing radiation reflected from the substrate portion with a recycling optical system; and
directing the reflected radiation back to the portion of the substrate using the recycling optical system to further heat the portion of the substrate.

43. The method of claim 42, wherein said focusing includes:
generating the annealing radiation with a two-dimensional array of laser diodes;
receiving the annealing radiation with an LTP optical system and forming therewith a radiation beam having a central angle at or near the Brewster's angle; and
wherein said radiation beam is adapted to focus the annealing radiation onto the substrate surface as the first line image.

44. The method of claim 42, wherein said directing includes causing the radiation reflected back to the substrate portion to be in the form of a recycling radiation beam having an angle that is at or near the Brewster's angle.

45. The method of claim 42, further including scanning the substrate relative to the annealing radiation.

46. The method of claim 42, wherein directing the reflected radiation back to the substrate portion includes reflecting the received radiation with a lens and a corner cube reflector.

47. The method of claim 42, wherein directing the reflected radiation back to the portion of the substrate includes:
forming a second image from the first image using the recycling radiation system and imaging the second image onto a diffraction grating oriented to ensure that the reflected radiation is directed back to the substrate in the form of a third image that is in focus in an image plane located at the substrate and that is parallel to the substrate.
